(19) United States
(12) Patent Application Publication
(10) Pub. No.: US 2006/0022281 A1
(43) Pub. Date: Feb. 2, 2006

(54) Semiconductor device

(75) Inventor: Toru Yamazaki, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/184,817

(22) Filed: Jul. 20, 2005

(30) Foreign Application Priority Data
Jul. 30, 2004 (JP) 2004-224341

(51) Int. Cl. H01L 29/94; H01L 29/76

(52) U.S. Cl. 257/392; 257/365; 257/407; 257/391

(57) ABSTRACT

There is provided a semiconductor device in which a plurality of field effect transistors with different breakdown voltage of a gate insulating film are provided on the same substrate by simple process. In the semiconductor device 100 having a high breakdown voltage transistor 102 and a low breakdown voltage transistor 104 formed on a silicon substrate 101, the gate impurity concentration of a polysilicon gate electrode film 117 of the high breakdown voltage transistor 102 is smaller than the gate impurity concentration of the low breakdown voltage transistor 104.

This application is based on Japanese patent application NO. 2004-224341, the content of which is incorporated hereinto by reference.

### BACKGROUND OF THE INVENTION

1. Field of the Invention

The present invention relates to a semiconductor device having transistors.

2. Description of Related Art

With respect to transistors, various kinds of characteristics are required according to an intended use or the like. For instance, electric field intensity, which is applied to a gate insulating film of a field effect transistor, varies depending on a using purpose or a setting position of the transistor. For this reason, in some cases, it is required that a plurality of transistors whose breakdown voltages of the gate insulating films are different are need to be fabricated on the same substrate. Conventionally, as for such technique, a technique to provide MOSFET (Metal Oxide Semiconductor Field Effect Transistor) with different film thicknesses of gate oxide films on the same substrate by a multi-oxide process is proposed (Japanese Laid-Open Patent Publication No. 2003-309188).

As described in the Japanese Laid-Open Patent Publication 2003-309188, in the technique of the multi-oxide process, after stripping apart of silicon oxide film formed on a surface of a silicon substrate, by repeating the step of forming another silicon oxide film, plural kinds of insulating films with different film thicknesses are formed. It is possible to change a breakdown voltage of the MOSFET upon changing a film thickness of the gate oxide film of the MOSFET.

However, in the multi-oxide process, the step to form an insulating film as the gate insulating film and to repeat a partial peeling has been complicated. For this reason, in the conventional method in which a plurality of transistors with different film thicknesses of the gate insulating films are manufactured on the single substrate, these steps constituted the factor in which the whole manufacturing process of the semiconductor device is complicated.

As described above, the conventional fabrication process of the field effect transistor by the multi-oxide process contained many of steps, and was complicated. In order to manufacture a plurality of field effect transistors with different breakdown voltages of the gate insulating films in a simple process, the invention from the viewpoint different than the multi-oxide process is to be needed.

The present inventor has achieved the present invention while performing examination earnestly upon aiming at manufacturing a plurality of transistors with different breakdown voltages of the gate oxide film without varying thickness of the gate insulating film, intentionally.

### SUMMARY OF THE INVENTION

According to the present invention, there is provided a semiconductor device comprising a semiconductor substrate, a first field effect transistor, having a first gate electrode film provided over the semiconductor substrate through a first gate insulating film, said first field effect transistor including a first impurity in the first gate electrode film, and a second field effect transistor having a second gate electrode film provided over the semiconductor substrate through a second gate insulating film, said second field effect transistor including a second impurity of the same conductivity type as the first impurity in the second gate electrode film, wherein, the first gate electrode film and the second gate electrode film comprise polycrystalline films containing Si, and a concentration of the first impurity in the first gate electrode film is smaller than a concentration of the second impurity in the second gate electrode film.

In the semiconductor device of the present invention, the concentration of the first impurity in the first gate electrode film is smaller than the concentration of the second impurity in the second gate electrode film. Thus, it is possible to make the breakdown voltage of the gate insulating film in the first field effect transistor higher than that of the gate insulating film in the second field effect transistor. Therefore, such configuration can be provided with a plurality of transistors of different breakdown voltage of the gate insulating film mounted on the same substrate by a simple manufacturing process, without varying the thickness of the gate insulating films.

In the semiconductor device of the present invention, the concentration of the first impurity in the first gate electrode film may be not more than 1×10¹⁹ atoms/cm³. This makes it possible to surely increase the breakdown voltage of the first gate insulating film.

In the semiconductor device of the present invention, the first gate electrode film may have a configuration not containing substantially the first impurity therein. Thus, it is possible to realize constitution where the semiconductor device is capable of being manufactured with further simple manufacturing process.

It should be noted that, in the present specification, “the impurity is not substantially contained” indicates that, in the manufacturing process of the first field effect transistor, the impurity is not doped intentionally into the first gate electrode film. Consequently, as a mode, which does not contain substantially the impurity, for instance, a mode in which the impurity is diffused from the air or the like into the first gate electrode film in the manufacturing process is included.

In the semiconductor device of the present invention, the concentration of the second impurity in the second gate electrode film may be larger than 1×10¹⁹ atoms/cm³. This makes it possible to suppress depletion of the gate in the second field effect transistor.

In the semiconductor device of the present invention, the first field effect transistor may further comprise a drain region provided in the semiconductor substrate, and a buried oxide film buried in the semiconductor substrate in a gate end part of the drain region. Thus, electric field centralization in the end portion of the gate electrode can be suppressed. Thereby, it is possible to improve further surely the breakdown voltage of the first field effect transistor.

In the semiconductor device of the present invention, the concentration of the second impurity in the second gate electrode film may be twice or more than twice of the concentration of the first impurity in the first gate electrode film. Having such configuration, it is possible to surely increase the breakdown voltage of the first gate insulating film in comparison with the second gate insulating film.

In the semiconductor device of the present invention, a thickness of the first gate insulating film may be substantially equal to a thickness of the second gate insulating film.

Any combination of the above configurations and converted expression of this invention, for example, between a process and an apparatus may be also effective as aspects of this invention.

For instance, according to the present invention, there is provided a method for manufacturing a semiconductor device that is the method for manufacturing the semiconductor device having a field effect transistor, comprising: setting a breakdown voltage of the field effect transistor; obtaining thickness of a depletion layer of a gate electrode of the field effect transistor related to magnitude of the breakdown voltage; setting concentration of a predetermined conductivity type impurity in the gate insulating film of the field effect transistor corresponding to the thickness of the depletion layer; and introducing the impurity into the gate insulating film depending on the impurity concentration.

Further, in the present invention, the second field effect transistor may be provided in an internal circuit region, and the first field effect transistor is provided in an I/O region provided on an outer peripheral part of the internal circuit region.

Furthermore, in the present invention, it is allowed that there is provided a silicide film on an upper part of the first gate electrode film or on an upper part of the second gate electrode film.

Moreover, in the present invention, the first gate insulating film may have the same material and thickness as the second gate insulating film. Thus, manufacturing of both of the first gate insulating film and the second gate insulating film is capable of being performed in the same process. Further, there is an advantage that manufacturing of both of the first gate insulating film and the second gate insulating film is completed by one time work.

According to the present invention, when providing a plurality of field effect transistors with different breakdown voltages of the gate insulating films on the same substrate, the technique for manufacturing the field effect transistors with simple process can be achieved by a configuration in which the concentration of the first impurity in the first gate electrode film is smaller than concentration of the second impurity in the second gate electrode film.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view schematically showing a constitution of a semiconductor device according to an embodiment;

FIG. 2 is a graph showing a relationship between a gate electrode impurity concentration and a width of gate depletion layer in a transistor of the semiconductor device according to the embodiment;

FIGS. 3A to 3D are cross-sectional views schematically showing a manufacturing process of the semiconductor device according to the embodiment;

FIG. 4 is a view schematically showing constitution of the semiconductor device according to the embodiment; and

FIG. 5 is a view explaining a method for designing the semiconductor device according to the embodiment.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purpose.

Hereinafter, there will be described embodiments of the present invention using drawings. In all the drawings, equivalent elements have the same symbol, whose description is not represented as appropriate.

(First Embodiment)

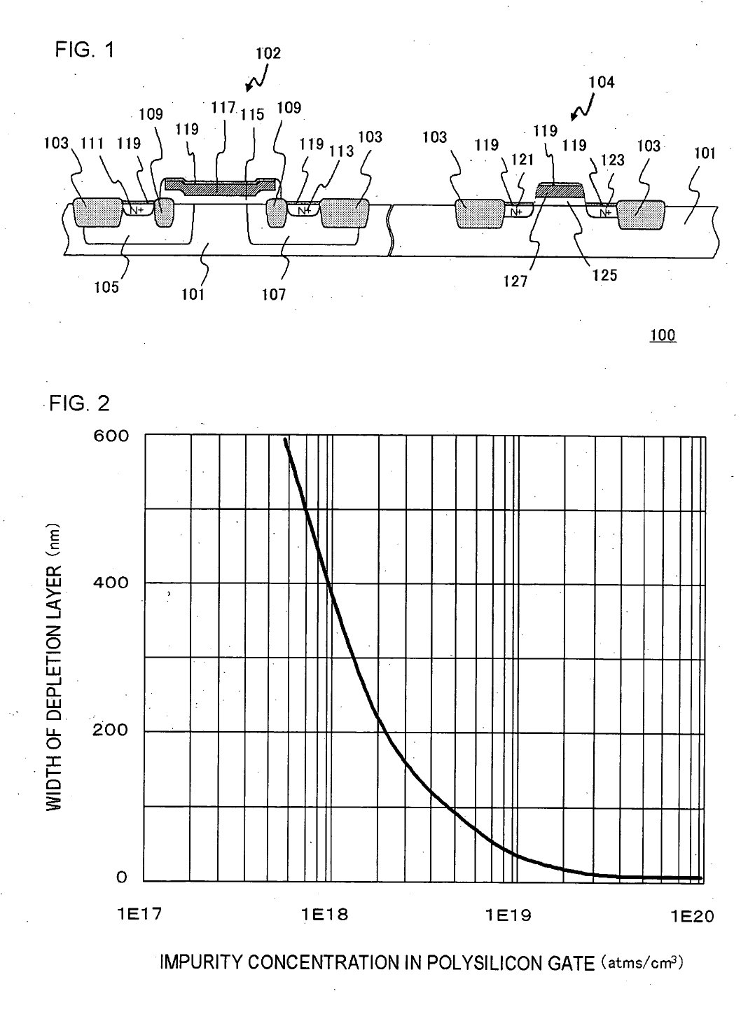

FIG. 1 is a cross-sectional view showing constitution of a semiconductor device 100 according to the present embodiment. The semiconductor device 100 shown in FIG. 1 has a high breakdown voltage transistor 102 and a low breakdown voltage transistor 104.

In the present embodiment and other embodiments below, the high breakdown voltage transistor 102 is a transistor whose breakdown voltage of a gate insulating film is higher than that of the low breakdown voltage transistor 104. Further, in the present embodiment and other embodiments, the low breakdown voltage transistor 104 indicates an ordinary transistor, which is not designed particularly as a high breakdown voltage transistor. The low breakdown voltage transistor 104 is a transistor, such as, for instance, a high-performance (high-speed) transistor, or a transistor with low power consumption, or the like.

In the present embodiment and the following embodiments, the low breakdown voltage transistor 104 constitutes an internal circuit of an LSI and the high breakdown voltage transistor 102 is provided on an I/O region. There will be described this constitution with this exemplification.

In the semiconductor device 100, a silicon substrate 101 is provided with a P well (not shown in the drawings) with conductivity type of P-type. The high breakdown voltage transistor 102 and the low breakdown voltage transistor 104 are formed in the P well. These transistors are provided on a region isolated by an element isolation region 103.

With the P well in the silicon substrate 101, there are provided an N well source 105 and an N well drain 107 as one pair of N-type impurity diffusion region, and a channel region (not shown in the drawings) is formed therebetween. There is provided a polysilicon gate electrode film 117 on the channel region. And, there is provided a CoSi₂ film 119 in which the polysilicon is made into silicide on upper surface of the polysilicon gate electrode film 117, so that the resistance is lowered. Further, a gate insulating film 115 is provided between the channel region and the polysilicon gate electrode film 117. Furthermore, a sidewall of the polysilicon gate electrode film 117 is cavered with a sidewall insulating film.

Moreover, in a region of an end part of the gate insulating film 115 of the N well drain 107, a buried oxide film 109 is provided in the silicon substrate 101. The polysilicon gate electrode film 117 is doped with N-type impurity.

Further, an N⁺ source 111 and an N⁺ drain 113, which are doped with N-type impurity, are provided on a region between the buried oxide film 109 and the N well source 105, and a region between the buried oxide film 109 and the N well drain 107 respectively. It should be noted that the CoSi₂ film 119 is also provided on the upper surfaces of the N⁺ source 111 and the N⁺ drain 113, so that the resistance is lowered. According to the above, the high breakdown voltage transistor 102 to be an N-type MOSFET is constituted.

Further, with the P well in the silicon substrate 101, there are provided an N⁺ source 121 and an N⁺ drain 123 as another one pair of N-type impurity diffusion region, and a channel region (not shown in the drawings) is formed therebetween. There is provided a polysilicon gate electrode film 127 on the channel region. A gate insulating film 125 is provided between the channel region and the polysilicon gate electrode film 127. Furthermore, a sidewall of the polysilicon gate electrode film 127 is covered with a sidewall insulating film (not shown in the drawings).

The polysilicon gate electrode film 127 is doped with N-type impurity. The CoSi₂ film 119 is formed on an upper surface of the polysilicon gate electrode film 127 and a surface of the N⁺ source 121 and N⁺ drain 123. According to the above, the low breakdown voltage transistor 104 to be an N-type MOSFET is constituted.

The polysilicon gate electrode film 117 and the polysilicon gate electrode film 127 are doped with the impurity. The polysilicon gate electrode film 117 and the polysilicon gate electrode film 127 are doped with the impurity of the same conductivity type. Here, there will be exemplified the case where the polysilicon gate electrode film 117 and the polysilicon gate electrode film 127 are doped with As as the impurity.

Here, according to the investigation of the present inventor about a relationship between an impurity concentration and a thickness of the gate depletion layer in the polysilicon as the material of the gate electrode, it has been found that there has been a relationship between them as shown in FIG. 2. FIG. 2 is a view showing the relationship between the impurity concentration (unit: atoms/cm³) and thickness of the gate depletion layer (unit: nm) in the polysilicon.

FIG. 2 indicates that it is possible to vary thickness of the gate depletion layer upon varying the impurity concentration with which the polysilicon gate electrode film 127 is doped. It is possible to vary the breakdown voltage of the high breakdown voltage transistor 102 upon varying thickness of the gate depletion layer. Therefore, the impurity quantity with which the polysilicon gate electrode film 127 is doped can be set in accordance with the breakdown voltage required of the high breakdown voltage transistor 102.

Specifically, the concentration of the impurity, As here, with which the polysilicon gate electrode film 117 of the high breakdown voltage transistor 102 is doped has smaller value than the concentration of As with which the polysilicon gate electrode film 127 is doped. For instance, the concentration of As in the polysilicon gate electrode film 117 of the high breakdown voltage transistor 102 is set to be not more than 1×10¹⁹ atoms/cm³. This makes it possible to surely enhance the breakdown voltage of the gate insulating film 125 of the high breakdown voltage transistor 102. Further, a lower limit of the As concentration in the polysilicon gate electrode film 117 is capable of being determined appropriately in accordance with the breakdown voltage of the high breakdown voltage transistor 102. For instance, the lower limit of the As concentration in the polysilicon gate electrode film 117 is set to be not less than 5×10¹⁷ atoms/cm³. Thus, it is possible to obtain the high breakdown voltage transistor 102 without thickening the gate insulating film 115 of the high breakdown voltage transistor 102 as compared with the gate insulating film 125 of the low breakdown voltage transistor 104.

Also, the concentration of As in the polysilicon gate electrode film 127 of the low breakdown voltage transistor 104 is set to be, for instance, the concentration larger than 1×10¹⁹ atoms/cm³, preferably not less than 1×10²⁰ atoms/cm³. Having such configuration, the gate electrode depletion of the low breakdown voltage transistor 104 can be suppressed. Further, the lower limit of the As concentration in the polysilicon gate electrode film 127 is suitably larger than the As concentration in the polysilicon gate electrode film 117. Furthermore, it is suitable that the As concentration in the polysilicon gate electrode film 127 is set to concentration, which minimize thickness of the depletion layer of the polysilicon gate electrode film 127 as small as possible.

Moreover, the As concentration in the polysilicon gate electrode film 127 is made intentionally different from the As concentration in the polysilicon gate electrode film 117. That is, difference between the As concentration in the polysilicon gate electrode film 127 and the As concentration in the polysilicon gate electrode film 117 does not fall within variation occurring unintentionally in a process, but has constitution where both concentrations are intentionally different from each other. For instance, the As concentration in the polysilicon gate electrode film 127 is set to be twice or more of the As concentration in the polysilicon gate electrode film 117.

Furthermore, particularly, it is suitable that the As concentration in the polysilicon gate electrode film 127 is at least ten fold or more of the As concentration in the polysilicon gate electrode film 117. Thereby, it is possible to certainly and sufficiently enhance the breakdown voltage of the gate insulating film 115. Consequently, the high breakdown voltage transistor 102 can surely have high breakdown voltage.

The element isolation region 103 and the buried oxide film 109 are, for instance, silicon oxide film. Further, the gate insulating film 115 and the gate insulating film 125 are the silicon oxide film.

Further, in the high breakdown voltage transistor 102 and the low breakdown voltage transistor 104, there is no limitation particularly, but the gate insulating film 115 and the gate insulating film 125, as described later, are formed in the same step, so these film thicknesses are formed to be approximately equal. Furthermore, in these transistors, the polysilicon gate electrode film 117 and the polysilicon gate electrode film 127 are formed in the same step, so these film thicknesses are formed to be approximately equal. Here, “these film thicknesses are formed to be approximately equal” indicates that the films may be formed without making the thicknesses of the films different intentionally. They may include variation, which takes place within the range formed in the same manufacturing step.

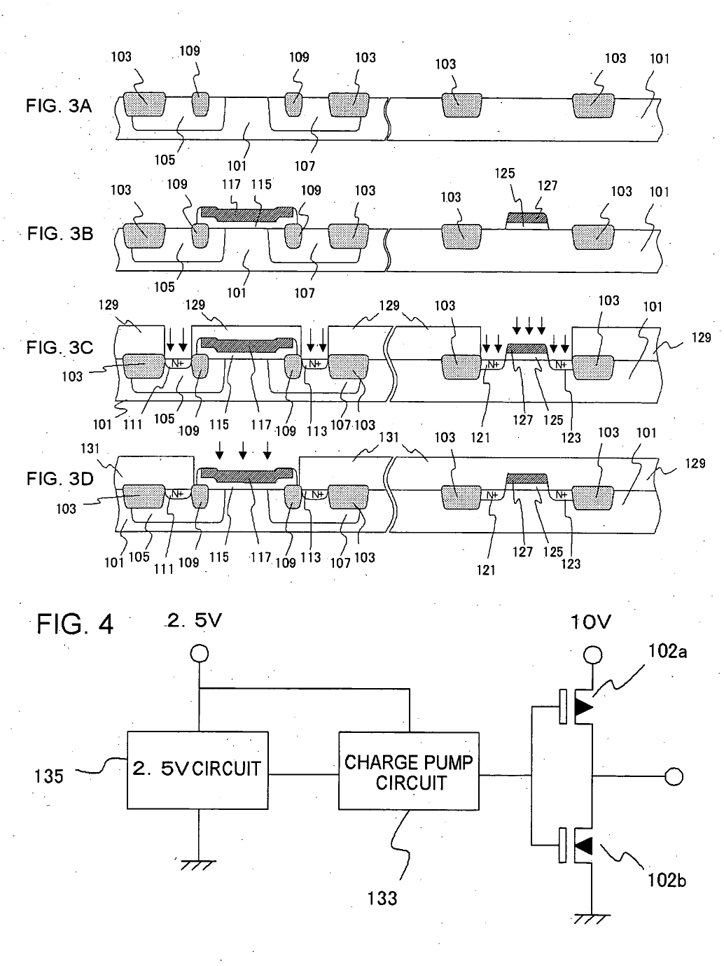

Next, there will be described a method for manufacturing the semiconductor device 100 shown in FIG. 1. FIGS. 3A to 3D are cross-sectional views showing one example of the manufacturing procedure of the semiconductor device 100 shown in FIG. 1.

Firstly, on the basis of the known techniques, the element isolation region 103 and the buried oxide film 109 are formed in a silicon substrate 101 as STI (Shallow Trench Isolation). The element isolation region 103 and the buried oxide film 109 are formed in the same step. The element isolation region 103 maybe formed by the other known methods, for instance, LOCOS method or the like. After that, the P well (not shown in the drawings) is formed while performing ion implantation of a P-type impurity into the silicon substrate 101. Moreover, the N well source 105 and the N well drain 107 are formed while doping an N-type impurity into the silicon substrate 101 (FIG. 3A). The N well source 105 and the N well drain 107 are low concentration source/drain regions.

Continuously, the gate insulating film 115 and the gate insulating film 125 are formed on a surface of the silicon substrate 101 in the same step. The gate insulating film 115 and the gate insulating film 125 are, for instance, an oxide film of 5 nm.

Next, a polycrystalline silicon film is formed on the gate insulating film 115 and the gate insulating film 125, as the polysilicon gate electrode film 117 and the polysilicon gate electrode film 127, respectively. Here, these gate electrode films are formed such that thicknesses of the polysilicon gate electrode film 117 and the polysilicon gate electrode film 127 are more than the thickness of the gate depletion layer of the polysilicon gate electrode film 117.

For instance, thicknesses of the polysilicon gate electrode film 117 and the polysilicon gate electrode film 127 are in the range of 200 to 400 nm, more specifically, 400 nm. At this time, the thickness of the gate depletion layer is 400 nm at a maximum. In this case, the As concentration in the polysilicon gate electrode film 117 is set to be around 1×10¹⁸ atoms/cm³ from FIG. 2.

Subsequently, the gate insulating film 115, the polysilicon gate electrode film 117, the gate insulating film 125 and the polysilicon gate electrode film 127 are subjected to a dry etching selectively and formed into a shape of the gate electrode. Further, on the buried oxide film 109, a sidewall insulating film is formed on sidewalls of the gate insulating film 115 and the polysilicon gate electrode film 117. Furthermore, on the P well of the silicon substrate 101, a sidewall insulating film (not shown in the drawings) is formed on sidewalls of the gate insulating film 125 and the polysilicon gate electrode film 127, (FIG. 3B). The sidewall insulating film can be formed by, for instance, anisotropic etching using fluorocarbon gas or the like.

Continuously, a resist 129 is patterned such as covering the gate insulating film 115 and the polysilicon gate electrode film 117. And then, the N⁺ source 111 and the N⁺ drain 113 are obtained while introducing the N-type impurity such as P or As into the N well source 105 and the N well drain 107. In this step, the N⁺ source 121 and the N⁺ drain 123 are formed while introducing the N-type impurity also into the P well surface and the polysilicon gate electrode film 127(FIG. 3C). It should be noted that, in the N⁺ source 121 and the N⁺ drain 123, a source/drain extension region may be formed as an electrical connecting part between the channel region and the impurity diffusion region.

Here, a dose amount of the impurity doped into the polysilicon gate electrode film 127 is determined in such a way that the impurity concentration in the polysilicon gate electrode film 127 is larger than 1×10¹⁹ atoms/cm³, for instance. The dose amount can be determined in accordance with the kind of the impurity element. Thereby, the configuration can surely be obtained which has the impurity concentration within the above range.

Next, the resist 129 is stripped, followed by performing patterning of the resist 131 and formed an opening at the upper part of the polysilicon gate electrode film 117. And then, ion implantation of the impurity into the polysilicon gate electrode film 117 is performed (FIG. 3D). The impurity dose amount doped into the polysilicon gate electrode film 117 is set to an amount in which the As concentration in the polysilicon gate electrode film 117 is smaller than the As concentration in the polysilicon gate electrode film 127. Thereby, a gate breakdown voltage of the high breakdown voltage transistor 102 is higher than the gate breakdown voltage of the low breakdown voltage transistor 104.

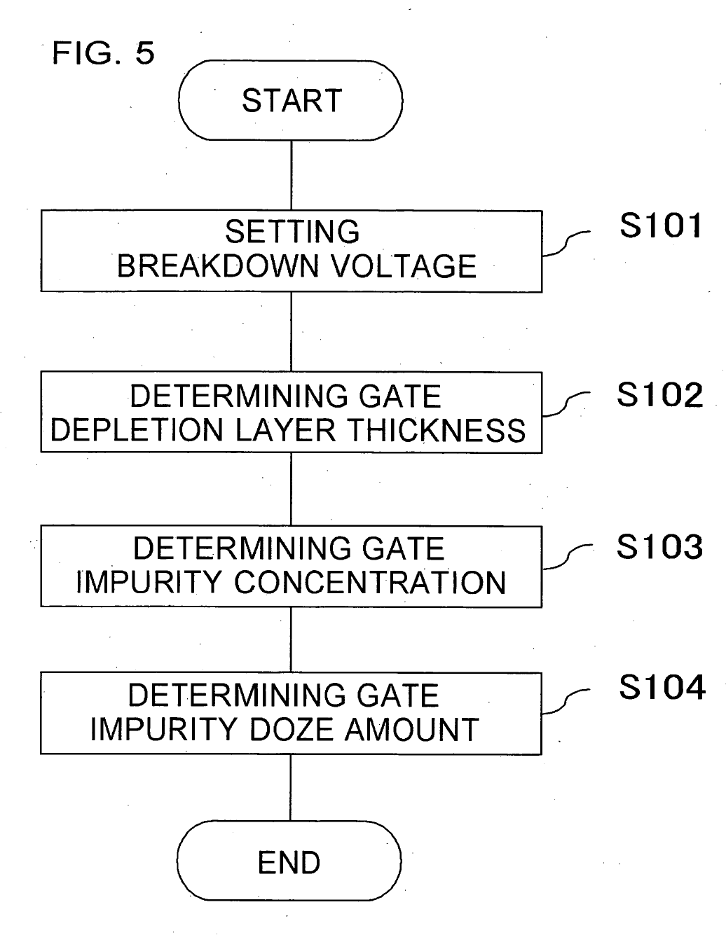

FIG. 5 is a view explaining a method for designing the high breakdown voltage transistor 102 in the step shown in FIG. 3D. In FIG. 5,. firstly, the breakdown voltage of the gate insulating film 115 is set in accordance with a position with which the high breakdown voltage transistor 102 is provided or the using purpose of the high breakdown voltage transistor 102 (S 101). Then, thickness of the gate depletion layer is set in accordance with the breakdown voltage set (S 102). The relationship between the breakdown voltage and the thickness of the gate depletion layer of the gate insulating film 115 is obtainable in advance. For example, the relationship can be obtained experimentally. Also, the relationship can be turned into a database. Specifically, the thickness of the gate depletion layer can be set by referring to a table which correlates the breakdown voltage of the gate insulating film 115 with the thickness of the gate depletion layer.

And then, the gate impurity concentration is determined based on the relationship shown in FIG. 2 described above, in accordance with the thickness of the gate depletion layer set at the step S 102 (S 103). The gate impurity concentration of the polysilicon gate electrode film 117 is set to be, for instance, 1×10¹⁸ atoms/cm³. Further, according to the thickness of the gate depletion layer, the film thicknesses of the polysilicon gate electrode film 117 and the polysilicon gate electrode film 127 formed together with the polysilicon gate electrode film 117 are determined. And then, dose amount of the impurity with which the polysilicon gate electrode film 117 is doped depending on the gate impurity concentration and the kind of the impurity element. The relationship between the gate impurity concentration and the dose amount is preliminarily acquired experimentally, for example, according to the kind of the impurity element.

After the step shown in FIG. 3D, the resist 131 is stripped, followed by performing the activation of the impurity by the heat treatment in a non-oxidative atmosphere. And then, CoSi₂ film 119 is formed on the polysilicon gate electrode film 117, thepolysilicongate electrode film 127, the N⁺ source 111, the N⁺ drain 113, the N⁺ source 121 and the N⁺ drain 123. The resistances of the gate electrodes can be reduced by being provided the CoSi₂ film 119. By the above processes, there is formed the semiconductor device 100 (FIG. 1) on which a plurality of transistors with different breakdown voltages are mounted together.

Next, there will be described effects of the semiconductor device 100 shown in FIG. 1.

In the semiconductor device 100 shown in FIG. 1, in the polysilicon gate electrode film 117 of the high breakdown voltage transistor 102 and the polysilicon gate electrode film 127 of the low breakdown voltage transistor 104, the impurity having same conductivity type is doped. The impurity concentration in the polysilicon gate electrode film 117 is smaller than the impurity concentration in the polysilicon gate electrode film 127. Thus, in the semiconductor device 100, it is possible to provide easily the transistors with different breakdown voltages of the gate oxide films on the same substrate, by intentionally differentiating the impurity concentration implanted into the polysilicon gate electrode film 117 and the polysilicon gate electrode film 127. This effect is remarkably achieved when the impurity concentration in the polysilicon gate electrode film 117 is set to be not more than 1×10¹⁹ atoms/cm³. Further, this effect is remarkably achieved when the impurity concentration in the polysilicon gate electrode film 127 is set to be not more than twice as much as the impurity concentration of the same conductivity type in the polysilicon gate electrode film 117.

Also, as described above using FIG. 2, in the semiconductor device 100, it is possible to control thickness of the gate depletion layer by adjusting the impurity concentration in the polysilicon gate electrode film 117 of the high break down voltage transistor 102. Thus, the breakdown voltage requested according to the purpose of use or the used position of the high breakdown voltage transistor 102 can surely be obtained by adjusting an added amount of the impurity. Further, the impurity concentration can be adjusted by adjusting the dose amount of the ion implantation, therefore, constitution within the above concentration range can be obtained stably with high reproducibility depending on adjustment of the dose amount.

Furthermore, the high breakdown voltage transistor 102 and the low breakdown voltage transistor 104 are materialized in such a way as to intentionally differentiate the impurity dose amounts doped into the polysilicon gate electrode film 117 and the polysilicon gate electrode film 127. These transistors can be obtained without differentiating film thickness of the gate insulating film. For this reason, it is possible to easily provide the transistors with different breakdown voltage on the same substrate by the simple manufacturing process without using complicated process such as a multi-oxide process or the like. Moreover, the semiconductor device has constitution capable of reducing the number of step of forming and stripping a photo resist, therefore, it is excellent in readily manufacturing. It is possible to improve reliability as the transistors about the high breakdown voltage transistor 102 and the low breakdown voltage transistor 104.

Further, the semiconductor device 100 can be obtained without differentiating the film thickness of the gate insulating film, therefore, device constitution is simplified and degree of freedom of the manufacturing process is improved. When applying voltage to the polysilicon gate electrode film 117 of the high breakdown voltage transistor 102, it is possible to surely extend the depletion layer to a side of the polysilicon gate electrode film 117. For this reason, the high breakdown voltage transistor 102 has the constitution which is capable of weakening the intensity of an electric field distributed to the gate insulating film 115. Consequently, it is possible to obtain the high breakdown voltage transistor 102 with predetermined breakdown voltage by adjusting the thickness of the gate depletion layer in such a way as to control the impurity doped into the polysilicon gate electrode film 117 while employing the film formation condition of the gate insulating film 115 or the polysilicon gate electrode film 117 as it is used in the existing process. Consequently, the semiconductor device 100 with excellent reliability can be obtained stably and with high yield by simple design change in accordance with magnitude of the breakdown voltage requested for the high breakdown voltage transistor 102.

(Second Embodiment)

In the semiconductor device 100 (FIG. 1) described in the first embodiment, the polysilicon gate electrode film 117 of the high breakdown voltage transistor 102 and the polysilicon gate electrode film 127 of the low breakdown voltage transistor 104 are doped with the same conductivity type impurity. However, non-doped constitution in which the impurity is not implanted intentionally into the polysilicon gate electrode film 117 may also be allowed.

Normally, a non-doped polysilicon is a P-type polysilicon, and has the impurity concentration of not more than around 10¹⁸ atoms/cm³. For this reason, on utilizing the non-doped polysilicon gate electrode film 117 as it is, the polysilicon gate electrode film 117 can be a gate electrode with high breakdown voltage in which the thickness of the gate depletion layer is sufficiently secured, . In this case, the semiconductor device according to the present embodiment can be obtained by executing steps of FIG. 3A to FIG. 3C in the same way as the first embodiment.

In the present embodiment, with respect to the polysilicon gate electrode film 117, it is possible to secure the thickness of the gate depletion layer sufficiently while the manufacturing process is simplified by employing constitution where the impurity of the predetermined conductivity type is not included substantially. Thereby, it is possible to form the transistors with different breakdown voltage of the gate oxide film on the same substrate by the simple method.

Further, in the present embodiment, it is possible to control extension of the gate depletion layer, that is, distribution ratio of the voltage to the polysilicon gate electrode film 117 and the gate insulating film 115, by adjusting the film thickness of the polysilicon gate electrode film 117 and the film thickness of the polysilicon gate electrode film 127 formed together.

(Third Embodiment)

The present embodiment relates to a high voltage output buffer using the semiconductor device 100 described in the above embodiments. Here, there will be described the case where the constitution of the first embodiment is applied as an example.

FIG. 4 is a view showing constitution of the semiconductor device according to the present embodiment. In FIG. 4, there is provided an inverter circuit in an I/O transistor 102a and a high breakdown voltage transistor 102b. The high breakdown voltage transistor 102a and the high breakdown voltage transistor 102b have constitution of the high breakdown voltage transistor 102 described in the first embodiment. The high breakdown voltage transistor 102a is a P channel MOS transistor, and the high breakdown voltage transistor 102b is an N channel MOS transistor.

Further, the semiconductor device shown in FIG. 4 has a charge pump circuit 133 connected with the high breakdown voltage transistor 102a and the high breakdown voltage transistor 102b, and a 2.5 V circuit 135 connected with the charge pump circuit 133. The 2.5 V circuit 135 is provided with the low breakdown voltage transistor 104 (FIG. 1) described in the first embodiment. A voltage of 2.5 V is applied to the 2.5 V circuit 135, and a voltage of 10 V is applied to a source of the high breakdown voltage transistor 102a. Further, the 2.5 V circuit 135 and the source of the high breakdown voltage transistor 102b are grounded.

In the semiconductor device shown in FIG. 4, for instance, with respect to the high breakdown voltage transistor 102a and the high breakdown voltage transistor 102b, the film thickness of the polysilicon gate electrode film 117 is set to be 400 nm, and the impurity concentration of the polysilicon gate electrode film 117 is set to be 1×10¹⁸ atoms/cm³. And then, there is applied voltage of 10 V to the gate electrodes of the high breakdown voltage transistor 102a and the high breakdown voltage transistor 102b. At this time, voltage of 2.5 V is distributed to the gate insulating film 115, and voltage or 7.5 V is distributed to the polysilicon gate electrode film 117.

Thus, the high breakdown voltage transistor 102a and the high breakdown voltage transistor 102b provided on a region where high voltage is applied to the polysilicon gate electrode film 117, make it possible to reduce magnitude of the voltage distributed to the gate insulating film 115. For this reason, it is possible to enhance the breakdown voltage of the gate insulating film 115, and it is possible to use it stably also in a condition high voltage is applied thereto.

Although the present invention has been described in details based on the preferred embodiments, it is to be understood that the embodiments are only exemplary, and that it is apparent to those skilled in the art that various modifications may be made without departing from the scope of the present invention.

For instance, in the high breakdown voltage transistor 102 and the low breakdown voltage transistor 104 used in the embodiments described above, the material of the gate electrode film used instead of the polysilicon may be poly-SiGe or the like. Using the poly-SiGe results in lowering the resistance of the gate electrode film.

Further, in the embodiments described above, there has been exemplified the case where the polysilicon gate electrode film 117 and the polysilicon gate electrode film 127 are doped with As as the impurity, it is also allowed that these gate electrode films are doped with the impurity of only the same conductivity type elements. For instance, it is possible to use As or P as the impurity. Furthermore, it is allowed that the polysilicon gate electrode film 117 and the polysilicon gate electrode film 127 are doped with the impurity of either different elements with the same conductivity type or the same element. By employing constitution where the impurity of the same element is implanted, it is possible to simplify the manufacturing process while the gate breakdown voltage of the respective transistors can surely be controlled. As the constitution where the impurity of the same element is implanted, the constitution in which P is doped into the polysilicon gate electrode film 117 and the polysilicon gate electrode film 127 can be cited.

Moreover, in the embodiments described above, the gate insulating film 115 and the gate insulating film 125 may be a film having higher dielectric constant than the silicon oxide film, that is, a high-k film. When employing the high-k film as the gate insulating film 115 and the gate insulating film 125, it is possible to constitute them by using materials with the specific dielectric constant of not less than 10. Specifically, the gate insulating film 115 and the gate insulating film 125 can respectively be composed of the materials containing one or not less than two elements selected from group consisted of Hf and Zr, so the gate insulating film 115 and the gate insulating film 125 can respectively be an oxide film, a silicate film or the like containing either of these elements. By utilizing such material, it is possible to increase the specific dielectric constant of the gate insulating film 115 and the gate insulating film 125, and to give an excellent heat resistance. Thereby, it is possible to contribute to reducing the size of MOSFET and improving the reliability. The gate insulating film 115 and the gate insulating film 125 can be composed of the same material, however, the both films can also be composed of different material.

Further, in the embodiments described above, there has been exemplified the case the polysilicon gate electrode film 117 and the polysilicon gate electrode film 127 are doped with the impurity having N-type of conductivity type, however, it is allowed that the impurity doped into these gate electrode films are only the same conductivity type, so it is possible to employ constitution where P-type impurity is doped. When there is employed constitution in which the P-type impurity is doped into the polysilicon gate electrode film 117 and the polysilicon gate electrode film 127, B may be used as the impurity doped into the polysilicon gate electrode film 117 and the polysilicon gate electrode film 127, for instance.

Furthermore, in the embodiments described above, it is allowed that the semiconductor device may have not less than three transistors. About at least two transistors among these transistors, it is allowed that the impurity, which is doped into the gate electrode film, is only the same conductivity type impurity. For instance, it is allowed that the low breakdown voltage transistor 104 may be one transistor constituting CMOS, which is provided in an internal circuit region, while the high breakdown voltage transistor 102 maybe the other transistor, which is provided in an I/O region.

### EXAMPLE

In the present example, the semiconductor device 100 (FIG. 1) described in the first embodiment has been manufactured. The film thickness of the polysilicon gate electrode film 117 of the high breakdown voltage transistor 102 was 400 nm. The impurity in the polysilicon gate electrode film 117 was P, and the concentration thereof was 1×10¹⁸ atoms/cm³. Further, the polysilicon gate electrode film 127 of the low breakdown voltage transistor 104 was manufactured in the same step of the polysilicon gate electrode film 117. And then, the impurity in the polysilicon gate electrode film 127 was P, and its concentration was 1×10²⁰ atoms/cm³.

The semiconductor device 100 obtained has operated stably, and further, the high breakdown voltage transistor 102 has been excellent in property of the breakdown voltage of the gate insulating film 115.

It is apparent that the present invention is not limited to the above embodiment that modified and changed without departing from the scope and sprit of the invention.

What is claimed is:

1. A semiconductor device comprising:
a semiconductor substrate;
a first field effect transistor having a first gate electrode film provided over said semiconductor substrate through a first gate insulating film, said first field effect transistor including a first impurity in said first gate electrode film; and
a second field effect transistor, having a second gate electrode film provided over said semiconductor substrate through a second gate insulating film, said second field effect transistor including a second impurity of the same conductivity type as said first impurity in said second gate electrode film,
wherein, said first gate electrode film and the second gate electrode film comprise polycrystalline films containing Si, and a concentration of said first impurity in said first gate electrode film is smaller than a concentration of said second impurity in said second gate electrode film.

2. The semiconductor device according to claim 1, wherein said concentration of said first impurity in said first gate electrode film is not more than 1×10¹⁹ atoms/cm³.

3. The semiconductor device according to claim 1, wherein said first gate electrode film does not contain substantially said first impurity.

4. The semiconductor device according to claim 1, said concentration of said second impurity in said second gate electrode film is larger than 1×10¹⁹ atoms/cm³.

5. The semiconductor device according to claim 1, wherein said first field effect transistor further comprises a drain region provided in said semiconductor substrate, and a buried oxide film buried in said semiconductor substrate, in a gate end part of said drain region.

6. The semiconductor device according to claim 1, wherein the concentration of said second impurity in said second gate electrode film is twice or more of said first impurity in said first gate electrode film.

7. The semiconductor device according to claim 1, wherein a thickness of said first gate insulating film is substantially equal to a thickness of said second gate insulating film.
